(19) United States
(12) Patent Application Publication
(10) Pub. No.: US 2022/0416097 A1
(43) Pub. Date: Dec. 29, 2022

(54) WAVEGUIDE PHOTODETECTORS FOR SILICON PHOTONIC INTEGRATED CIRCUITS

(71) Applicant: Intel Corporation, Santa Clara, CA (US)

(72) Inventors: David Kohen, Rio Rancho, NM (US); Kelly Magruder, Albuquerque, NM (US); Parastou Fakhimi, Albuquerque, NM (US); Zhi Li, San Jose, CA (US); Cung Tran, Niskayuna, NY (US); Wei Qian, Walnut, CA (US); Mark Isenberger, Corrales, NM (US); Mengyuan Huang, Cupertino, CA (US); Harel Frish, Albuquerque, NM (US); Reece DeFrees, Rio Rancho, NM (US); Ansheng Liu, Cupertino, CA (US)

(73) Assignee: Intel Corporation, Santa Clara, CA (US)

(21) Appl. No.: 17/358,921

(22) Filed: Jun. 25, 2021

(51) Int. Cl. H01L 31/0232; G02B 6/12; H01L 31/105; H01L 31/107; H01L 31/18

(52) U.S. Cl. CPC H01L 31/02327; G02B 6/12; H01L 31/105; H01L 31/1075; H01L 31/1804; G02B 2006/12061; G02B 2006/12097

(57) ABSTRACT

A photodetector structure over a partial length of a silicon waveguide structure within a photonic integrated circuit (PIC) chip. The photodetector structure is embedded within a cladding material surrounding the waveguide structure. The photodetector structure includes an absorption region, for example comprising Ge. A sidewall of the cladding material may be lined with a sacrificial spacer. After forming the absorption region, the sacrificial spacer may be removed and passivation material formed over a sidewall of the absorption region. Between the absorption region an impurity-doped portion of the waveguide structure there may be a carrier multiplication region, for example comprising crystalline silicon. If present, edge facets of the carrier multiplication region may be protected by a spacer material during the formation of an impurity-doped charge carrier layer. Occurrence of edge facets may be mitigated by embedding a portion of the photodetector structure with a thickness of the waveguide structure.

### BACKGROUND

A photonic integrated circuit (PIC) includes integrated photonic devices or elements. PICs are preferred to optical systems built with discrete optical components and/or optical fiber because of their more compact size, lower cost, heightened functionality, and/or performance Silicon PICs (SiPh) have one or more planar silicon photonic waveguide structures of a diameter less than 1 μm, which convey light within the PIC. These planar silicon waveguides terminate at an optical output coupler (OC) suitable for coupling to an optical fiber array (FA) comprising fibers, which may have diameters on the order of a hundred microns, for example.

For optical-to-electrical conversion, a PIC may include a photodetector (PD). A PD may be a diode having a mesa structure abutting a waveguide structure of the PIC. Alternatively, a PD may be formed over a length of the waveguide. Relative to mesa-type PD structures, such waveguide PD structures offer superior light absorption and scalability. However, waveguide PD structures present a number of challenges that hinder their high volume manufacture.

### BRIEF DESCRIPTION OF THE DRAWINGS

The material described herein is illustrated by way of example and not by way of limitation in the accompanying figures. For simplicity and clarity of illustration, elements illustrated in the figures are not necessarily drawn to scale. For example, the dimensions of some elements may be exaggerated relative to other elements for clarity. Further, where considered appropriate, reference labels have been repeated among the figures to indicate corresponding or analogous elements. In the figures:

FIG. 1 is a top-down plan view of a PIC including a PD over a length of an optical waveguide, in accordance with some embodiments;

FIG. 2 is a flow diagram of methods for fabricating a waveguide PD with sidewall passivation, in accordance with some embodiments;

FIGS. 3A, 3B, 3C, 3D, 3E and 3F are cross-sectional views of the PIC depicted in FIG. 1 along the a-a′ line as operations in the methods shown in FIG. 2 are practiced, in accordance with some embodiments;

FIGS. 4, 5 and 6 are cross-sectional views of the PIC depicted in FIG. 1 along the a-a′ line following formation of a passivation layer, in accordance with two alternative embodiments;

FIG. 7A is a cross-sectional view of the PIC depicted in FIG. 1 along the a-a′ line upon completion of the methods shown in FIG. 2, in accordance with some embodiments;

FIG. 7B is a cross-sectional view of the PIC depicted in FIG. 1 along the b-b′ line upon completion of the methods shown in FIG. 2, in accordance with some embodiments;

FIG. 8 is a flow diagram of methods for fabricating a waveguide avalanche PD with spacer-based formation of a charge carrier layer, in accordance with some embodiments;

FIGS. 9A, 9B, 9C, 9D, 9E and 9F are cross-sectional views of the PIC depicted in FIG. 1 along the a-a′ line as operations in the methods shown in FIG. 8 are practiced, in accordance with some embodiments;

FIG. 10A is a cross-sectional view of the PIC depicted in FIG. 1 along the a-a′ line upon completion of the methods shown in FIG. 8, in accordance with some embodiments;

FIG. 10B is a cross-sectional view of the PIC depicted in FIG. 1 along the b-b′ line upon completion of the methods shown in FIG. 8, in accordance with some embodiments;

FIG. 11 is a flow diagram of methods for fabricating a waveguide avalanche PD with a recessed carrier multiplication region, in accordance with some embodiments;

FIGS. 12A, 12B, 12C, 12D, 12E and 12F are cross-sectional views of the PIC depicted in FIG. 1 along the a-a′ line as operations in the methods shown in FIG. 11 are practiced, in accordance with some embodiments;

FIG. 13A is a cross-sectional view of the PIC depicted in FIG. 1 along the a-a′ line upon completion of the methods shown in FIG. 11, in accordance with some embodiments;

FIG. 13B is a cross-sectional view of the PIC depicted in FIG. 1 along the b-b′ line upon completion of the methods shown in FIG. 11, in accordance with some embodiments;

FIG. 14 illustrates a mobile computing platform and a data server machine employing an optical receiver module including a PIC having a waveguide PD, in accordance with some embodiments; and

FIG. 15 is a functional block diagram of an electronic computing device, in accordance with an embodiment.

### DETAILED DESCRIPTION OF EXEMPLARY EMBODIMENTS

Embodiments are described with reference to the enclosed figures. While specific configurations and arrangements are depicted and discussed in detail, it should be understood that this is done for illustrative purposes only. Persons skilled in the relevant art will recognize that other configurations and arrangements are possible without departing from the spirit and scope of the description. It will be apparent to those skilled in the relevant art that techniques and/or arrangements described herein may be employed in a variety of other systems and applications other than what is described in detail herein.

Reference is made in the following detailed description to the accompanying drawings, which form a part hereof and illustrate exemplary embodiments. Further, it is to be understood that other embodiments may be utilized and structural and/or logical changes may be made without departing from the scope of claimed subject matter. It should also be noted that directions and references, for example, up, down, top, bottom, and so on, may be used merely to facilitate the description of features in the drawings. Therefore, the following detailed description is not to be taken in a limiting sense and the scope of claimed subject matter is defined solely by the appended claims and their equivalents.

In the following description, numerous details are set forth. However, it will be apparent to one skilled in the art, that embodiments may be practiced without these specific details. In some instances, well-known methods and devices are shown in block diagram form, rather than in detail, to avoid obscuring the embodiments. Reference throughout this specification to “an embodiment” or “one embodiment” or “some embodiments” means that a particular feature, structure, function, or characteristic described in connection with the embodiment is included in at least one embodiment. Thus, the appearances of the phrase “in an embodiment” or “in one embodiment” or “some embodiments” in various places throughout this specification are not necessarily referring to the same embodiment. Furthermore, the particular features, structures, functions, or characteristics may be combined in any suitable manner in one or more embodiments. For example, a first embodiment may be combined with a second embodiment anywhere the particular features, structures, functions, or characteristics associated with the two embodiments are not mutually exclusive.

As used in the description and the appended claims, the singular forms “a”, “an” and “the” are intended to include the plural forms as well, unless the context clearly indicates otherwise. It will also be understood that the term “and/or” as used herein refers to and encompasses any and all possible combinations of one or more of the associated listed items.

The terms “coupled” and “connected,” along with their derivatives, may be used herein to describe functional or structural relationships between components. It should be understood that these terms are not intended as synonyms for each other. Rather, in particular embodiments, “connected” may be used to indicate that two or more elements are in direct physical, optical, or electrical contact with each other. “Coupled” may be used to indicated that two or more elements are in either direct or indirect (with other intervening elements between them) physical or electrical contact with each other, and/or that the two or more elements co-operate or interact with each other (e.g., as in a cause and effect relationship).

The terms “over,” “under,” “between,” and “on” as used herein refer to a relative position of one component or material with respect to other components or materials where such physical relationships are noteworthy. For example in the context of materials, one material or layer over or under another may be directly in contact or may have one or more intervening materials or layers. Moreover, one material between two materials or layers may be directly in contact with the two materials/layers or may have one or more intervening materials/layers. In contrast, a first material or layer “on” a second material or layer is in direct physical contact with that second material/layer. Similar distinctions are to be made in the context of component assemblies.

As used throughout this description, and in the claims, a list of items joined by the term “at least one of” or “one or more of” can mean any combination of the listed terms. For example, the phrase “at least one of A, B or C” can mean A; B; C; A and B; A and C; B and C; or A, B and C.

Unless otherwise specified in the explicit context of use, the term “predominantly” means more than 50%, or more than half. For example, a composition that is predominantly a first constituent means more than half of the composition is the first constituent (e.g., <50 at. %). The term “primarily” means the most, or greatest, part. For example, a composition that is primarily a first constituent means the composition has more of the first constituent than any other constituent. The term “substantially” means there is no more than incidental variation from a target value. For example, a composition that is substantially a first constituent means the composition may further include only trace levels of any substitutional constituent.

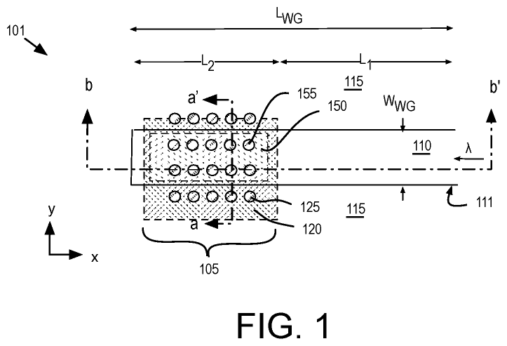

FIG. 1 is a plan view of a PIC 101 that may be fabricated over any suitable substrate. PIC 101 includes a photonic or optical waveguide structure 110. Optical waveguide structure 110 is of a material having sufficient index contrast with a surrounding optical cladding material 115 to guide by total internal reflection (TIR) electromagnetic waves in the optical spectrum (hv) along a longitudinal waveguide length L_{WG}. Waveguide structure 110 has a rib or ridge sidewall 111 defining a transverse waveguide width W_{WG}. Width W_{WG} may vary with material system and wavelength, but for some embodiments where waveguide structure 110 is crystalline silicon, W_{WG} may range from 0.4 to 2 μm, for example. Along a waveguide length L₁, cladding material 115 is adjacent to sidewall 111 and over a top surface of waveguide structure 110. However, along waveguide length L₂, a waveguide photodetector (PD) 105 is embedded within cladding material 115. Hence, over waveguide length L₂ cladding material 115 is absent from at least the top surface of waveguide structure 110. Waveguide length L₂ may vary with implementation, but in some examples ranges from 5 to 75 μm.

As described further below, the architecture of PD 105 may vary. In some embodiments described further below, PD 105 is a p-i-n photodiode. In other embodiments described further below, PD 105 is an avalanche photodiode. In accordance with exemplary embodiments, PD 105 includes an absorption material (not visible in FIG. 1) between a first (bottom) impurity region 120 having a first electrical conductivity type (e.g., n-type) and a second (top) impurity region 150 of a second electrical conductivity type (e.g., p-type). Each of impurity regions 120, 150 is illustrated in dashed line to emphasize these impurity regions are subsurface, below overlying material. Contact metallization 125 contacts impurity region 120 and contact metallization 155 contacts impurity region 150.

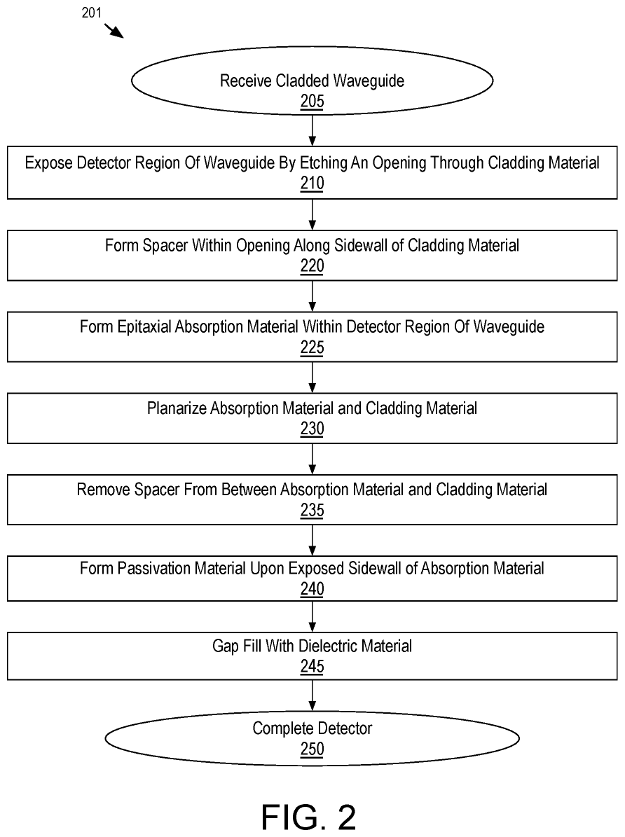

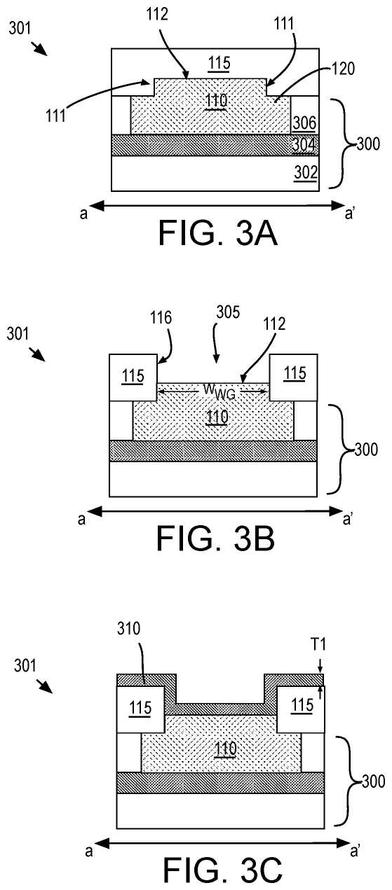

FIG. 2 is a flow diagram of methods 201 for fabricating a waveguide PD with sidewall passivation, in accordance with some embodiments. In methods 201, a passivation material is formed in direct contact with at least a sidewall of an absorption material. The passivation material may reduce leakage current of the PD, for example by reducing recombination of charge carriers at the sidewall of the absorption material. Methods 201 integrate the passivation material into a waveguide PD structure through the use of a sacrificial spacer, at least some of which is replaced with the passivation material. Features of PIC 101 (FIG. 1) in accordance with embodiments herein are further illustrated FIG. 3A-3F along a cross-sectional plane taken at the a-a′ line depicted in FIG. 1.

Referring first to FIG. 2, methods 201 begin at input 205 where a cladded photonic waveguide structure is received. At block 210, a length of the waveguide structure where a photodetector is to be formed is exposed by etching an opening through the cladding material. Any patterning process known to be suitable for the cladding material may be practiced at block 210. For example, a photolithographic masking process followed by a plasma/dry etch may be practiced to form an opening or window over a predetermined length of the waveguide structure.

FIG. 3A illustrates a waveguide PD structure 301, which is one exemplary embodiment of waveguide PD structure 101 (FIG. 1). As shown in FIG. 3A, waveguide structure 110 between sidewalls 111 is defined in a device layer 306 of a substrate 300. Substrate 300 may be any substrate known in the art to be suitable for forming an IC, such as, but not limited to, a semiconductor-on-insulator (SOI) substrate. In advantageous embodiments, device layer 306 is a crystalline (e.g., substantially monocrystalline) semiconductor layer. In exemplary embodiments, device layer 306 is (mono)crystalline silicon. Device layer 306 may also be of an alternative semiconductor material, such as germanium, SiGe, or other compound semiconductors, such as InP.

Substrate 300 includes an intervening material 304 between device layer 306 and a carrier material 302. Intervening material 304 is advantageously of high index contrast with the device layer 306 to ensure high confinement of optical modes within waveguide structure 110. In the exemplary embodiments where device layer 306 and carrier material 302 are both (mono)crystalline silicon, intervening material 304 is silica (SiO₂). Hence, where substrate 300 is a silicon SOI substrate, a silicon photonic waveguide structure 110 is patterned into a silicon device layer 306.

Optical modes are confined within waveguide structure 110 by optical cladding material 115. As shown, cladding material 115 is adjacent to waveguide sidewall 111, and may be in direct contact with waveguide sidewall 111. Cladding material 115 is also over a top surface 112 of waveguide structure 110, for example being in direct contact with waveguide top surface 112. Although the chemical composition of cladding material 115 may vary, in exemplary embodiments where waveguide structure 110 is substantially silicon, cladding material 115 is silica (SiO₂) Cladding material 115 may further include various impurities, such as, but not limited to carbon, hydrogen, or nitrogen.

FIG. 3A further illustrates impurity region 120. As shown, impurity region 120 has transverse width exceeding that of waveguide structure 110. Hence, both waveguide structure 110 and a portion of device layer 306 beyond sidewalls 111 comprises impurities imparting the semiconductor material with a first conductivity type. In some exemplary embodiments, the semiconductor material within impurity region 120 is n-type and comprising donor impurities, such as phosphorus, arsenic, or antimony. The impurity concentration within impurity region 120 may vary with implementation, however in some specific examples the n-type impurity concentration is between 1e18 and 1e20 atom/cm³. In some alternative embodiments, impurity region 120 is p-type, comprising acceptor impurities, such as boron.

FIG. 3B further illustrates an exemplary opening 305 patterned into cladding material 115. As shown, an anisotropic etching process has formed a cladding sidewall 116. Top waveguide surface 112 is exposed at a bottom of opening 305. Opening 305 may have any transverse width, and, in this example is substantially equal to transverse waveguide width W_{WG}. Although not visible in FIG. 3B, opening 305 may have any longitudinal width.

Returning to FIG. 2, methods 200 continue at block 220 where a spacer is formed within the opening patterned at block 210. The spacer is to be retained only along the sidewall of the cladding material. The spacer is sacrificial and therefore may be of any chemical composition that can be subsequently removed with good selectivity relative to other materials of the PIC. FIG. 3C illustrates an exemplary embodiment where a layer of spacer material 310 is conformally deposited, for example with a chemical vapor deposition (CVD) process, to predetermined thickness T₁. Although thickness _{T1} may vary with implementation, in some exemplary embodiments thickness T₁ is at least 5 nm and may be 10 nm, or more. Spacer material 310 has a different chemical composition than cladding material 115. In exemplary embodiments where cladding material comprises primarily silicon and oxygen, spacer material 310 comprises silicon and more nitrogen than cladding material 115. Spacer material 310 may be Si₃N₄, for example, or a silicon oxynitride (SiNO_{X}).

As further illustrated in FIG. 3B, spacer material 310 is etched back with an anisotropic etch process to leave a spacer 311 of controlled lateral width W_{S} lining a sidewall of the cladding material 115. The spacer etch process may be any plasma/dry process offering sufficient etch selectivity relative to cladding material 115. Although lateral width W_{S} may vary with implementation, in some exemplary embodiments lateral width W_{S} is at least 5 nm and may be 10 nm, or more.

Returning to FIG. 2, methods 201 continue at block 225 where absorption material is formed over the remaining area of the exposed waveguide top surface. In exemplary embodiments, the absorption material is formed with an epitaxial growth process with the top waveguide surface being a seed for (mono)crystalline growth of the absorption material. The absorption material may have any chemical composition known to be suitable for absorbing light of a particular wavelength λ. The absorption material may substantially fill the remainder of the opening etched into the cladding material, and physically contact the spacer that lines the cladding material opening.

At block 230, overburden of the absorption material growth may be removed with any planarization process suitable for the materials present. In exemplary embodiments, the chemical mechanical polish process planarizes a top surface of the absorption material with a top surface of the surround cladding material. In the example illustrated in FIG. 3E, absorption material 330 has been epitaxially grown upon surface 112 of waveguide structure 110 and planarized with cladding material 115. A surface of spacer 311 is exposed by the planarization process.

Absorption material 330 may have any chemical composition and any microstructure. In exemplary embodiments, absorption material 330 comprises Ge, is advantageously predominantly Ge, and is more advantageously primarily Ge. In some embodiments, absorption material 330 is substantially pure Ge. Donor and/or acceptor impurity concentration within absorption material 330 is low, and advantageously at an intrinsic level with no intentional donor or acceptor impurities. In other embodiments, absorption material 330 is a GeSi alloy or III-V semiconductor, such as but not limited to GaAs, which may be grown on a seed surface of Ge, for example.

Absorption material 330 may have any microstructure. In some exemplary embodiments, absorption material 330 is crystalline, and more specifically substantially monocrystalline. Absorption material 330 may be either strained or relaxed, depending on the thickness and lattice (mis)match with seed surface 112. In exemplary embodiments where waveguide structure 110 is crystalline Si and absorption material 330 is crystalline Ge, absorption material 330 may be selectively grown upon seed surface 112 to form a relaxed single crystal of Ge having the same lattice orientation as that of waveguide structure 110. Hence, where seed surface 112 is a (100) plane, a absorption material top surface 312 is also a (100) plane.

As shown in FIG. 3E, a sidewall 315 of absorption material 330 is in direct physical contact with spacer 311. The inventors have found that such an epitaxial semiconductor-dielectric (e.g., Ge—SiO₂) interface can suffer high electrical leakage currents, perhaps as a result of a high number of defect states and/or charge carrier traps, etc. However, with a top surface of spacer 311 now exposed by the planarization of absorption material 330, methods 201 (FIG. 2) continue at block 235 where the spacer is removed from between the absorption and cladding materials.

Any selective etch process suitable for the compositions of the spacer, cladding material and absorption material may be practiced at block 235. As a sacrificial mandrel, the spacer is removed to expose a sidewall of the absorption material. Then, at block 240, a passivation material is formed at least on the sidewall of the absorption material. Block 240 may entail any surface treatment of the absorption material known to be suitable for passivating the surface. For example, a plasma treatment may react one or more of sulfur, hydrogen, oxygen, or nitrogen with the absorption material to form a passivation. In some embodiments, a material layer may by deposited onto exposed surfaces of the absorption material at block 240. For example, an epitaxial growth process, or CVD (ALD) deposition process may be practiced to deposit a passivation material either selectively upon surfaces of the absorption material, or unselectively over all surfaces of the workpiece. As described further below, the passivation material may be deposited conformally or non-conformally.

In the example illustrated in FIG. 3F, a selective etch of spacer 311 leaves an opening 340. Absorption material sidewall 315 defines an inner diameter of opening 340 and cladding material sidewall 116 defines an outer diameter of opening 340. Opening 340 is therefore a trench or mote surrounding absorption material 330. At least a portion of opening 340 traverses a width of waveguide structure 110, where seeding surface 112 is exposed. One or more passivation treatments and/or material deposition process may be performed to passivate absorption material 330 and/or reclad waveguide structure 110 exposed by opening 340.

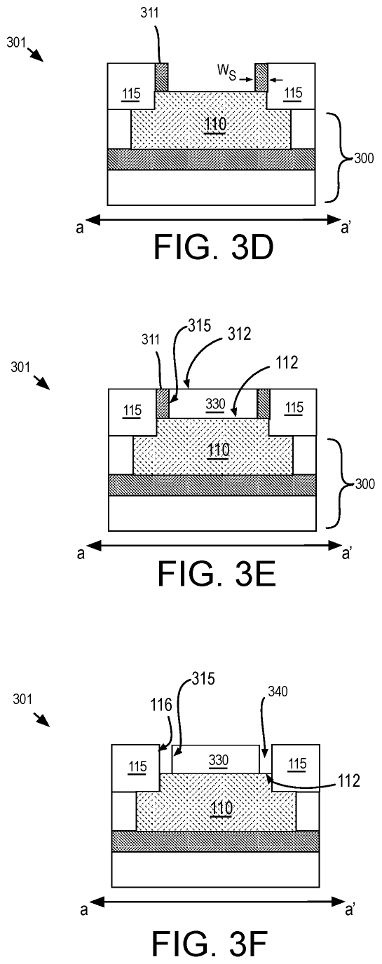

FIG. 4 illustrates one example where a substantially conformal passivation material layer 345 is deposited upon both absorption material top surface 312 and sidewall 315. Passivation material 345 has been non-selectively deposited, and therefore is also on the cladding material 115, including sidewall 116. In this example passivation material 345 has a sidewall passivation thickness T₂, as measured substantially normal to absorption material sidewall 315, that is less than half the lateral spacer width Wₛ (FIG. 3D). Although the sidewall passivation thickness T₂ may vary, in some examples thickness T₂ is no more than 2 nm. Because thickness T₂ is less than half spacer width Wₛ, seeding surface 112 is covered by a passivation material foot 445.

As noted above, passivation material 345 may have any chemical composition known to reduce surface states that facilitate electrical leakage/charge carrier recombination. In some examples where absorption material 330 is predominantly, primarily, or substantially pure Ge, passivation material 345 comprises silicon. As one example, passivation material 345 is an epitaxial (mono)crystalline Si layer. For such embodiments, the silicon layer may have a thickness T₂ of <2 nm, which may be below the critical thickness so that the Si layer is strained to lattice match absorption material 330. In other embodiments, passivation material 345 may be an oxide or nitride of absorption material 330. For example, in some embodiments where absorption material 330 is Ge, passivation material 345 is GeOₓ. In other embodiments, passivation material 345 is GeNₓ or GeOₓN_{y}. Such materials may be either formed through a surface reaction with absorption material 330 or through a cyclic atomic layer deposition process. In ALD embodiments, a Ge precursor may be absorbed to sidewall 315 (and cladding material 115) during a first ALD phase, and then the absorbed Ge precursor may be oxidized or nitridized with a second precursor during a second ALD phase. Any number of cycles including these two phases may be performed to obtain a desired thickness T₂.

FIG. 5 illustrates an example where passivation material 345 is selective deposited upon absorption material 330 and waveguide structure 110. For such embodiments, passivation material 345 may be formed through a surface reaction such as a thermal and/or plasma oxidation, nitridation, hydration, sulfination, etc. Alternatively, ALD embodiments may be selective to only absorption material 330. In the example illustrated in FIG. 5, passivation material 345 again has thickness T2 distal from waveguide structure 110 and, because of foot 445, passivation material 345 has a greater thickness T3 proximal to waveguide structure 110. Where passivation material 345 completely covers the bottom of opening 340 (FIG. 3F), thickness T₃ is approximately equal to spacer width Wₛ (FIG. 3D). As such, the passivation material thickness may vary along sidewall 315.

Returning to FIG. 2, methods 201 proceed at block 245 where any gaps, for example between the absorption material and cladding material, are optionally filled with a dielectric material. Gap filling at block 245 may entail any dielectric deposition process, such as, but not limited to flowable/curable CVD or a liquid dispense/cure process. Methods 201 are then completed at output 250, for example with the fabrication of a second (top) detector electrical terminal. Any number of interconnect levels may also be fabricated at output 250, for example to interconnect individual detector terminals into addressable arrays.

In the example illustrated in FIG. 6, waveguide PD structure 301 is substantially as described above in the context of FIG. 5 with the addition of a gap fill dielectric material 655 between passivation material 345 and cladding material 115. Dielectric material 655 is drawn in dashed line to emphasize it may be absent from embodiments where passivation material 345 substantially fills opening 340 (FIG. 3F). Dielectric material 655 may have any composition suitable as an IC insulation film, such as, but not limited to, silicon dioxide, silicon nitride, or silicon oxynitride. Dielectric material 655 may further comprise one or more impurities, such as, but not limited to carbon and hydrogen. In other embodiments, dielectric material 655 is an organic material, such as, but not limited to, polyimide. As further illustrated in FIG. 6A, a planarization process has removed passivation material 345 from absorption material top surface 312.

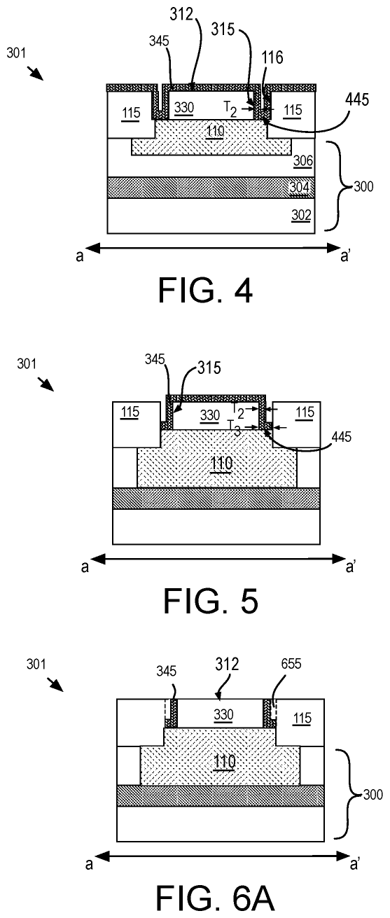

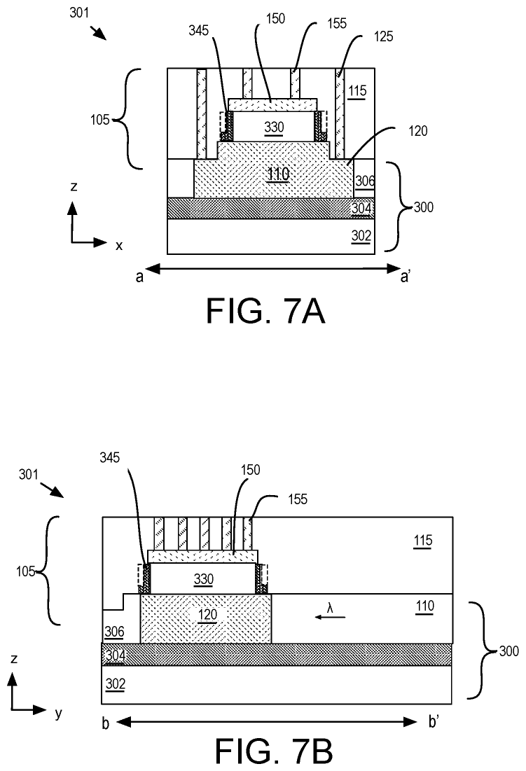

FIG. 7A and FIG. 7B illustrate waveguide PD structure 301 following completion of methods 201 (FIG. 2). As illustrated, impurity region 150 is over absorption material 330. In this example, impurity region 150 is in direct contact with absorption material top surface 312. Impurity region 150 may have any chemical composition suitable for making a good semiconductor-metal contact with contact metallization 155. In some embodiments, impurity region 150 comprises silicon, and is advantageously predominantly silicon and more advantageously primarily silicon. Impurity region 150 may have any microstructure including epitaxial single crystalline, polycrystalline with or without texture, or amorphous.

Impurity region 150 comprises donor/acceptor impurities of a complementary conductivity type as impurity region 120. In exemplary embodiments where impurity region 120 is n-type (having donor impurities), impurity region 150 is p-type (having acceptor impurities). P-type impurity concentrations with impurity region 150 may vary with implementation, for example from 1e16-5e18 atoms/cm³. In some alternative embodiments where impurity region 120 is p-type, impurity region 150 is n-type.

As further illustrated in FIGS. 7A and 7B, contact metallization 155 is in direct physical contact with impurity region 150, and contact metallization 125 similarly in direct physical contact with impurity region 120. Contact metallizations 125, 155 may each be any suitable metallization, such as, but not limited to, Cu, W, Ti, Pt, Co, Ta, and their nitrides, silicides, carbides, or oxides. Contact metallizations 125, 155 extend through dielectric material that may be of the same or a different composition as that of cladding material 115.

As noted above, a waveguide photodetector may comprise a carrier (avalanche) multiplication region. Such an avalanche photodetector (APDs) may offer higher performance relative to a P-i-N structure lacking carrier multiplication. The passivation methods, passivation material structures described above are also applicable to APDs. As described further below, APD architectures present additional challenges associated with the formation of a charge carrier layer and an avalanche charge carrier multiplication region.

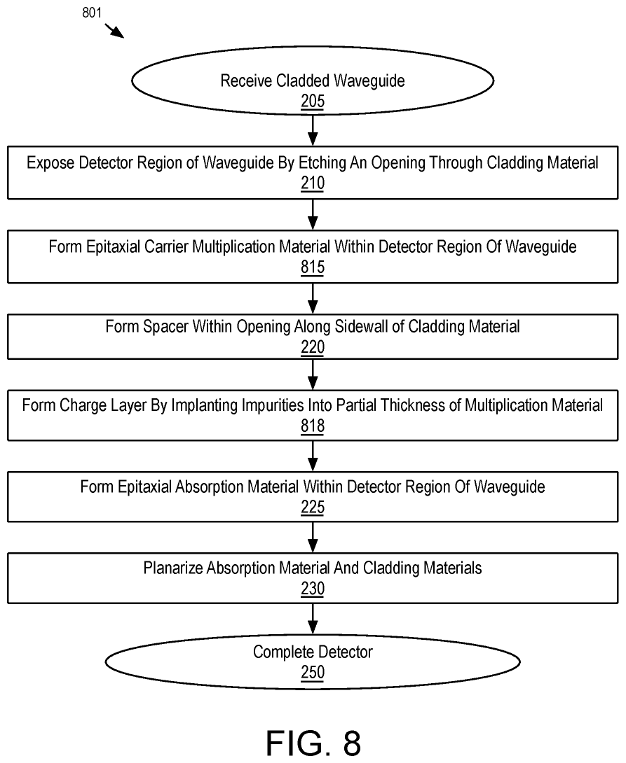

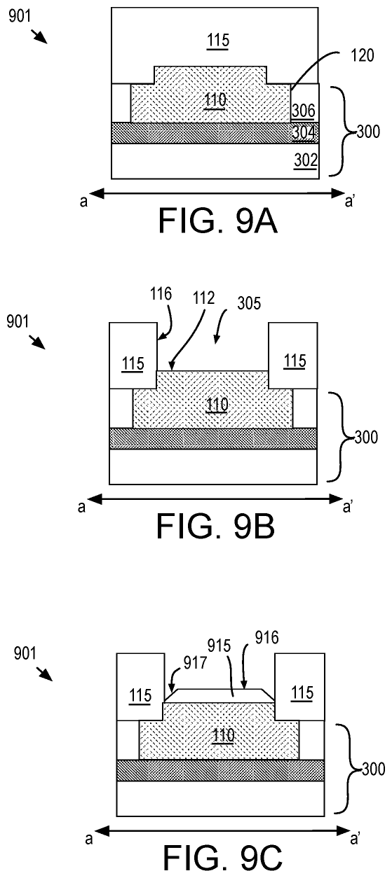

FIG. 8 is a flow diagram of methods 801 for fabricating a waveguide APD with spacer-based formation of a charge carrier layer, in accordance with some embodiments. In methods 801, a spacer is formed as self-aligned structure that confines the subsequent formation of a charge carrier layer to primarily one facet of a crystalline multiplication material. The inventors have determined confinement of the charge layer to primarily the (100) facet improves detector functionality and reliability. The inventors have noted advantages to avoiding significant impurity concentrations within regions proximal to higher index facets, such as (111), (113), (119) planes. FIG. 9A-9F are cross-sectional views of the PIC depicted in FIG. 1 along the a-a′ line as operations in the methods 801 are practiced, in accordance with some embodiments.

Referring first to FIG. 8, methods 801 again begin at input 205 where a cladded waveguide structure is received. The cladded waveguide structure may have any of the attributes described above in the context of input 205. At block 210, a detector region of the waveguide is exposed by etching an opening through the cladding material.

FIG. 9A illustrates one exemplary waveguide APD structure 901, which at this point in manufacture includes waveguide structure 110 within SOI substrate 300. Cladding material 115 is over an entirety of waveguide structure 110. Waveguide structure 110 comprises impurity region 120. Each of the structures illustrated in FIG. 9A referenced with a number previously described may have any of the attributes previously described. For example waveguide structure 110 may be (mono)crystalline silicon, and impurity region 120 may be comprising n-type/donor impurities. FIG. 9B illustrates an opening 305 through cladding material 115, defining cladding sidewall 116 and exposing waveguide top surface 112, substantially as described above.

Returning to FIG. 8, methods 801 continue at block 815 where carrier multiplication material is epitaxially grown upon the waveguide surface exposed within the detector region of the waveguide structure. In exemplary embodiments, the carrier multiplication material is a (mono)crystalline semiconductor material epitaxially grown from a seeding surface of the waveguide structure. As illustrated in FIG. 9C, carrier multiplication material 915 is epitaxially grown upon waveguide surface 112. Although the composition of the carrier multiplication material 915 may vary with implementation, in exemplary embodiments carrier multiplication material 915 is predominantly silicon, advantageously primarily silicon, and more advantageously substantially pure silicon. Donor/acceptor impurity concentration within carrier multiplication material 915 is lower than within impurity region 120. Impurity concentrations within carrier multiplication material 915 is advantageously at an intrinsic level.

As shown in FIG. 9C, the epitaxial growth of carrier multiplication material 915 proceeds at rates that are dependent upon the crystal facet at the growth front. In this example, the (100) facet advances more rapidly than higher index facet 917, which may be any of a (111) facet, (113) facet, (119) facet, etc. As a result of differential growth rates, the lowest index facet 916 will become smaller as the thickness of carrier multiplication material 915 increases.

Returning to FIG. 8, methods 801 continue at block 220 where a spacer is formed within the opening along a sidewall of the cladding material. Any of the spacer formation techniques described above may be practiced to form any of the spacer structures described above. FIG. 9D illustrates spacer 311 along cladding material sidewall 116. Spacer 311 again requires no lithographic mask patterning as it is instead self-aligned to cladding material sidewall 116 as a result of topography and anisotropic etch back.

Although spacer 311 may be substantially the same as discussed above, spacer width Wₛ is more specifically large enough for spacer 311 to fully mask at least one higher index facet 917. As there may be more than one higher index facet 917 (e.g., both (111) and (113) facets may be present), spacer width Wₛ is at least sufficient to completely cover the (111) facet, which is the higher index facet expected to have the largest surface area. Since the lateral width of higher index facet 917 increases with thickness of cladding material sidewall 116. Spacer width Wₛ is approximately equal to thickness T₄ of carrier multiplication material 915. In some examples where carrier multiplication material thickness T₄ is 50-500 nm, spacer width Wₛ is 50-500 nm.

With the self-aligned spacer masking the higher index growth plane(s) near the perimeter of the detector region, methods 801 (FIG. 8) continue at block 818 where a charge carrier layer is formed within the unmasked detector region by implanting impurities into a partial thickness of the multiplication material. The impurities introduced at block 818 are confined by the spacer to be proximal to only the (100) plane of the of the multiplication material. Higher index planes of the multiplication material will not be dosed with impurities. In the example illustrated in FIG. 9E, a charge carrier layer 918 has been dosed with impurities. Although the polarity of impurities may be either n-type or p-type, for exemplary embodiments where multiplication material 915 is crystalline silicon, charge carrier layer 918 is advantageously p-type. Dopant concentrations may vary with implementation. In some examples, doping concentration with charge carrier layer 918 is between 1e16 and 1e18 atoms/cm³. As illustrated, charge carrier layer 918 does not intersect higher index plane 917 with the portion of multiplication material 915 proximal to higher index plane 917 remaining at a much lower electrical conductivity (e.g., associated with an intrinsic impurity level).

Following formation of the charge layer, methods 801 (FIG. 8) continue with epitaxial growth of the absorption material at block 225, planarization of the absorption material with the surrounding cladding material at block 230, and completion of the detector structure at block 250. Any of the techniques and/or structures described above in the context of methods 201 may be likewise practiced and/or formed during the practice of methods 801. For example, as shown in FIG. 9F absorption material 330 has been epitaxially grown over a seeding surface 912 of charge carrier layer 918 (which is an impurity region of multiplication material 915). In exemplary embodiments, absorption material 330 is substantially pure, intrinsic Ge. However, alternative materials are also possible, as noted above. As further illustrated in FIG. 9F, absorption material 330 has been planarized with a surface of cladding material 115.

In accordance with some embodiments, as further illustrated in FIG. 9G, planarization may continue to a point where spacer 311 is exposed, allowing for spacer 311 to be removed substantially as described above for methods 201 (FIG. 2). Hence, blocks 235 and 240 may be practiced as part of methods 801 to similarly form passivation material 345 on a sidewall of absorption material 330. As further illustrated, passivation material 345 may also be formed on higher index plane 917. The composition of passivation material 345 on higher index plane 917 may differ from the composition of passivation material 345 on sidewall 315, for example as a function of the different compositions of multiplication material 915 and absorption material 330.

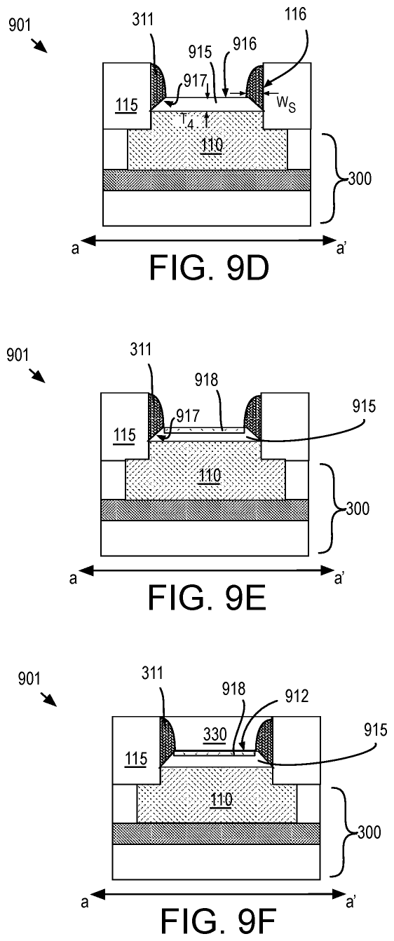

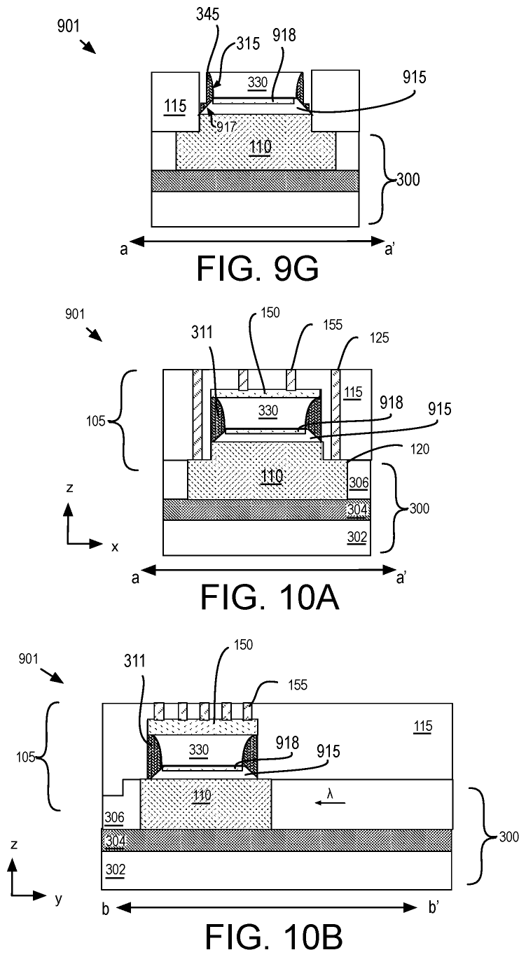

FIG. 10A is a cross-sectional view of the PIC 101 depicted in FIG. 1 along the a-a′ line for some embodiments where waveguide detector 105 is an APD. FIG. 10B is a cross-section view of the PIC 101 depicted in FIG. 1 along the b-b′ line, in accordance with some embodiments where waveguide detector 105 is an APD. As shown, waveguide detector 105 further includes impurity region 150. In exemplary embodiments, impurity region 150 has conductivity complementary to that of impurity region 120. For example, impurity region 150 is advantageously p-type Si. Dopant concentration within impurity region 150 may vary with some examples being 1e¹⁸-1e²⁰ atoms/cm³. Contact metallization 125 and 155 are in physical contact with impurity region 120 and impurity region 150, respectively.

The typical tradeoff between responsivity and bandwidth for a given thickness of absorption material can be altered when the majority optical mode traversing the waveguide more fully occupies the absorption material. Because of the additional thickness of materials intervening between absorption material and an underlying waveguide structure, it is particularly challenging to achieve a high responsivity for APD architectures. To retain their function, the multiplication material and/or charge carrier layer require some threshold thickness. Likewise, a reduction in impurity region thickness at terminals of the detector increases series/external resistance, which reduces detector bandwidth.

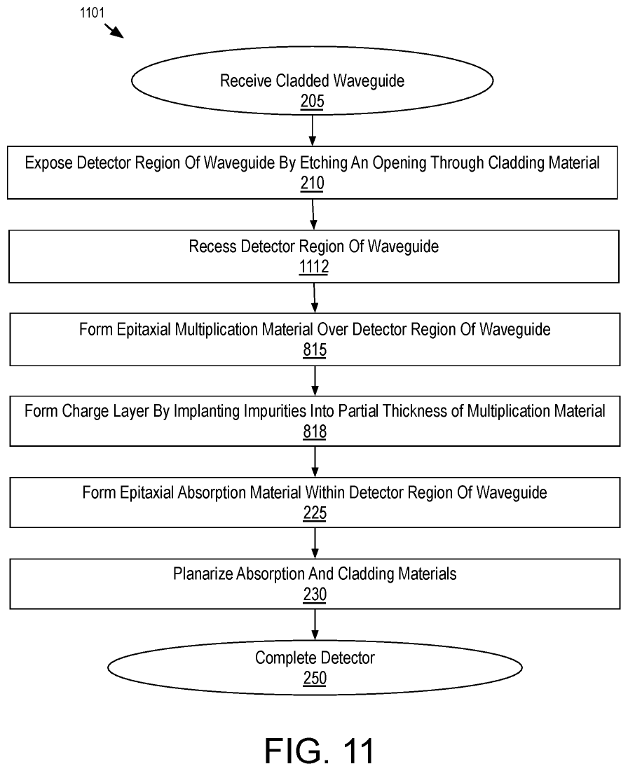

In accordance with some embodiments, a detector structure is recessed within the detector portion of a waveguide. Embedding the detector structure within a recess located in a top surface of a waveguide structure can improve responsivity of the detector for a given detector bandwidth while still retaining sufficient material thicknesses for avalanche gain and low external/series resistance. FIG. 11 is a flow diagram of methods 1101 for fabricating a waveguide APD with a recessed carrier multiplication region, in accordance with some embodiments. Although methods 1101 are directed at fabricating a recessed waveguide APD, methods 1101 may also be practiced to fabricate a recessed photodetector of any other architecture, such as, but not limited to a P-i-N PD.

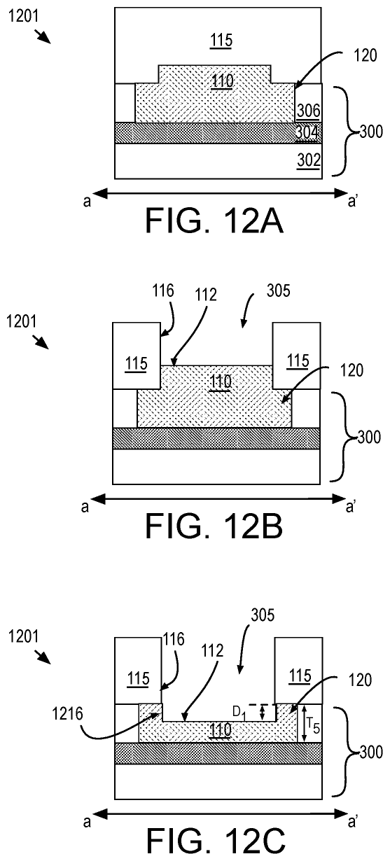

In methods 1101, a detector portion of a waveguide is etched following the patterning of an overlying cladding material. The inventors have determined that recessing at least a portion of the detector (e.g., a multiplication region) can reduce faceting during selective epitaxial growth, ensuring a large flat surface plane for the various detector material layers. Recessing at least a portion of the detector also reduces the physical spacing between a waveguide structure and absorption material of the detector. FIG. 12A-12F are cross-sectional views of the PIC depicted in FIG. 1 along the a-a′ line as operations in the methods 1101 are practiced, in accordance with some embodiments.

Referring first to FIG. 11, methods 1101 again begin at input 205 where a cladded waveguide structure is received. The cladded waveguide structure may have any of the attributes described above in the context of input 205. At block 210, a detector region of the waveguide is exposed by etching an opening through the cladding material.

FIG. 12A illustrates one exemplary waveguide APD structure 1201, which at this point in manufacture includes waveguide structure 110 within SOI substrate 300, and cladding material 115 over an entirety of waveguide structure 110. Waveguide structure 110 comprises impurity region 120. Each of the structures illustrated in FIG. 12A referenced with a number previously described may have any of the attributes previously described. For example, waveguide structure 110 may be (mono)crystalline silicon, and impurity region 120 may be n-type, further comprising donor impurities. FIG. 12B illustrates opening 305 through cladding material 115, defining cladding sidewall 116 and exposing waveguide top surface 112, substantially as described above.

Returning to FIG. 11, methods 1101 continue at block 1112 where the detector region of the waveguide structure exposed by the opening in the cladding material is etched to recess the top surface of the waveguide structure. The etch process performed at block 1112 may be selective to the waveguide structure with the cladding material and/or a photoresist mask masking a remainder of the waveguide structure. The etch process may be any dry/plasma or wet chemical process known to be suitable for the composition of the waveguide structure.

In the example further illustrated in FIG. 12C, waveguide top surface 112 is recessed by a depth D1 within opening 305. Depth D1 is advantageously less than device layer thickness T5, which may again vary from 200-500 nm, for example. In exemplary embodiments depth D1 is 30-80% of thickness T5. This range of recess depth will ensure impurity region 120 has some material thickness (T5−D1) directly under multiplication and/or absorption regions that will be formed within opening 350. Around the perimeter of the detector region, impurity region 120 has the full thickness T5, which will provide a low resistance connection to a contact metal. As further illustrated, the waveguide recess within opening 305 is defined by an interior sidewall 1216, which in this example is aligned with cladding material sidewall 116. The alignment between sidewalls 1216 and 116 is indicative of waveguide structure 110 having been recessed with an anisotropic dry etch. For embodiments where waveguide structure 110 comprises (mono)crystalline silicon, the waveguide recess etch may employ one or more of Cl₂, SF₆, NF₃, or HBr, for example.

With the detector region of the waveguide recessed, methods 1101 (FIG. 11) continue at block 815 with epitaxial growth of the multiplication material. Block 815 may be practiced substantially as described above in the context of methods 801. However, because of the waveguide recess, the seeding surface includes the interior sidewall of waveguide structure 110. Because of this additional growth surface, high index faceting is reduced and may be completely avoided. For example, as further illustrated in FIG. 12D, multiplication material 915 is epitaxially grown from top surface 112 (e.g., a (100) plane) and also from sidewall 1216 (e.g., a (001) plane). Depending on the epitaxial growth process, multiplication material 915 may be grown for a certain duration before cladding material 115 may begin to induce some higher index faceting along sidewall 116. With the epitaxial growth not initially pinned at the sidewall, multiplication material top surface 916, which is a low index (e.g., (100)) plane, can span the entire detector region and make physical contact with sidewall 116. Although the multiplication material thickness T₄ may again vary with implementation, in some examples where T₅ is 200-500 nm and D1 is 60-400 nm, T₄ is 50-500 nm so that multiplication material top surface 916 may be slightly below, substantially planar with, or slightly proud of, the waveguide top surface beyond the detector region.

In absence of any higher index faceting, methods 1101 may proceed at block 818 where a charge layer is formed, for example by implanting impurities (e.g., acceptors) into a partial thickness of the multiplication material. Alternatively, the charge layer may be formed by introducing impurities (e.g., acceptors) in-situ during a last portion of the epitaxial growth of the multiplication material. Optionally, an ion implant process performed at block 818 may be masked, for example with a photoresist, to confine impurities to a region smaller than that of the opening in cladding material. Optionally, a self-aligned spacer may be formed (e.g., substantially as described for methods 801), and that spacer employed as a mask to space the charge layer from the sidewall of cladding material. Methods 1101 then continue through blocks 225, 230 and 250, for example substantially as described above.

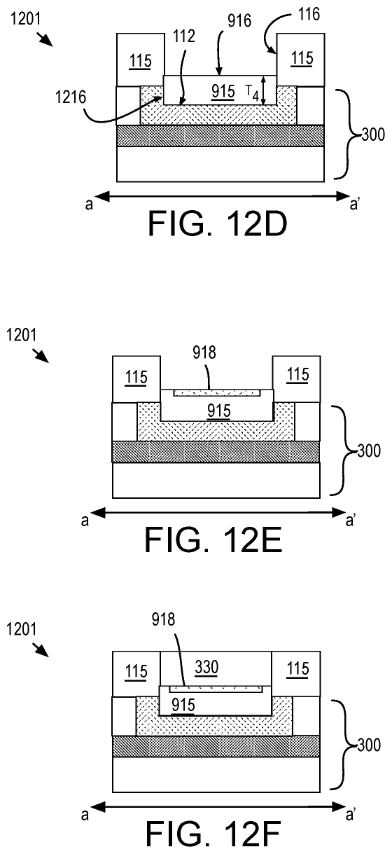

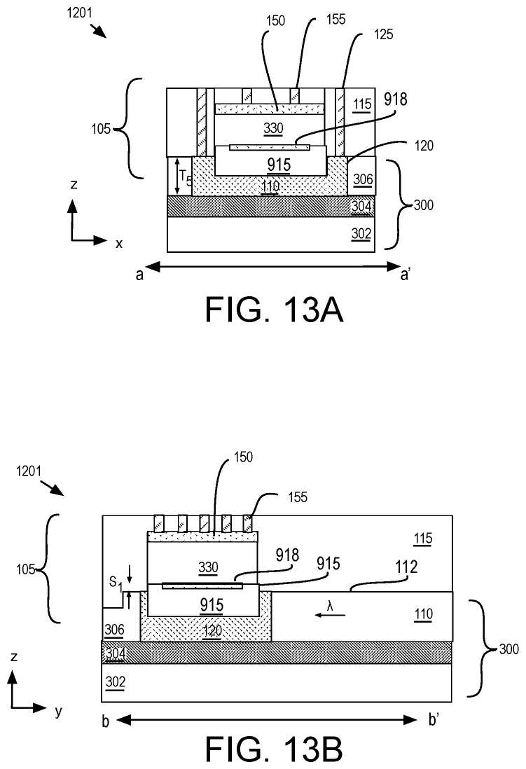

FIG. 12E further illustrates charge layer 918, which again comprises more impurities (e.g., acceptors) than multiplication material 915. In FIG. 12F, adsorption material 330 (e.g., intrinsic Ge) has been epitaxially grown over charge layer 918 (and multiplication material 915) and planarized with cladding material 115. FIG. 13A is a cross-sectional view of the PIC depicted in FIG. 1 along the a-a′ line upon completion of the methods 1101, in accordance with some embodiments. Contact metallization 125 is in direct contact with impurity region 120 where impurity region 120 is at thickness T5. Impurity region 150 is substantially planar over an entirety of the detector region because faceted epitaxial growths were avoided. As shown again in FIG. 13A, multiplication material 915 is epitaxial material that has been grown within a recess of impurity region 110.

FIG. 13B is a cross-sectional view of the PIC depicted in FIG. 1 along the b-b′ line upon completion of the methods 1101, in accordance with some embodiments. As shown, a bottom surface of absorption material 330 is separated from a waveguide structure top surface 112 by a space S₁, which may vary with implantation. In some examples, space S₁ is no more than 200 nm, and advantageously 100 nm, or less. Absorption efficiency may accordingly be increased for a given waveguide length L₂ occupied by the detector. Alternatively, a detector occupying a shorter waveguide length L₂ may achieve a given absorption efficiency. As capacitance is less for shorter detector lengths, detector bandwidth may be increased for a given quantum efficiency.

Although not illustrated, spacer formation and/or spacer replacement as described elsewhere herein may also be implemented within methods 1101 (FIG. 11). For example, blocks 235 and 240 (FIG. 2) may be practiced as part of methods 1101 to similarly form a passivation material on a sidewall of the absorption material substantially as described elsewhere herein.

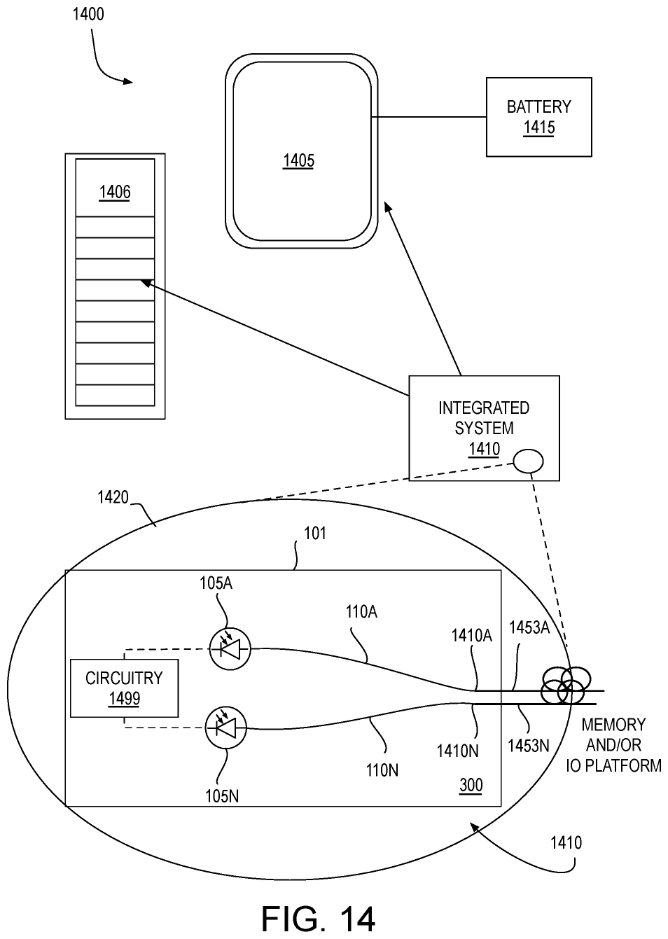

FIG. 14 illustrates a mobile computing platform 1405 and a data server machine 1406 employing an optical receiver module 1420 including PIC 101 having waveguide photodetectors 105A, 150N, in accordance with one or more embodiments described herein. Server machine 1406 may be any commercial server, for example including any number of high performance computing platforms disposed within a rack and networked together for electronic data processing, which in the exemplary embodiment includes an integrated system 1410. Mobile computing platform 1405 may be any portable device configured for each of electronic data display, electronic data processing, wireless electronic data transmission, or the like. For example, mobile computing platform 1405 may be any of a tablet, a smart phone, laptop computer, etc., and may include a display screen (e.g., a capacitive, inductive, resistive, touchscreen), a chip-level or package-level integrated system 1410, and a battery 1415.

PIC 101 includes waveguide structures 110A and 110N in accordance with embodiments. Optical fiber 1453A inputs an optical beam into photonic waveguide 110A, for example through a fiber coupler 1410A. Optical fiber 1453N inputs an optical beam into photonic waveguide 110N, for example through a fiber coupler 1410N. Optical waveguides 110A-110N are coupled into a waveguide photodetector structures 105A, 105N, for example as described elsewhere herein. Photodetectors 105A-105N are electrically coupled to downstream integrated circuitry 1499, which may for example further include a voltage supply and sense circuitry. In certain embodiments, voltage supply and sense circuitry is implemented with CMOS transistors also on substrate 300, and powered at a voltage level no less than that at which the photodetectors are operated. Although not depicted, PIC 101 may further include an optical de-multiplexer, such as an Echelle grating WDM, or AWG WDM, etc.

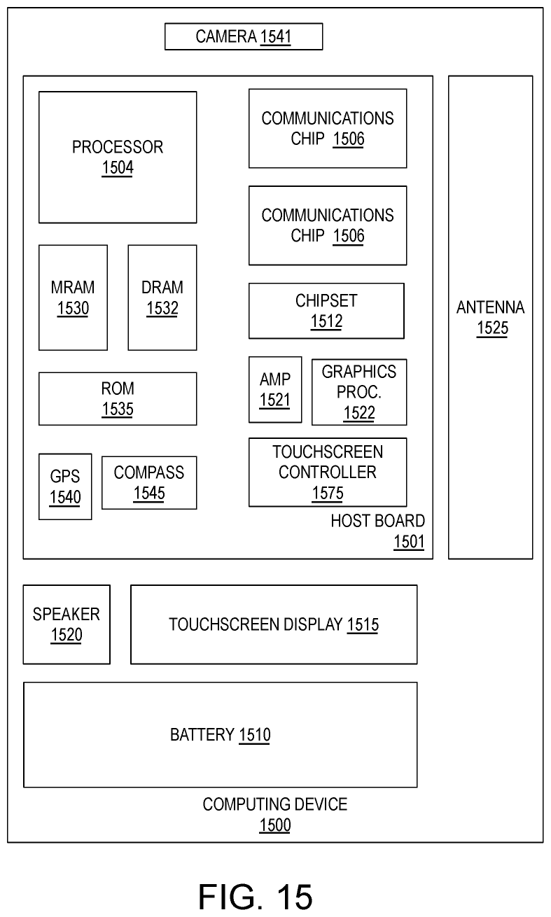

FIG. 15 is a functional block diagram of an electronic computing device, in accordance with some embodiments. Computing device 1500 may be found inside platform 1405 or server machine 1406, for example. Device 1500 further includes host board 1501 hosting a number of components, such as, but not limited to, a processor 1504 (e.g., an applications processor. In some examples, one or more of the components of device 1500 includes a PIC chip with a waveguide photodetector, for example as described elsewhere herein. In general, the term “processor” or “microprocessor” may refer to any device or portion of a device that processes electronic data from registers and/or memory to transform that electronic data into other electronic data that may be further stored in registers and/or memory.

In various examples, one or more communication chips 1506 may also be physically and/or electrically coupled to processor 1504. Depending on its applications, computing device 1500 may include other components that may or may not be physically and electrically coupled to motherboard 1502. These other components include, but are not limited to, volatile memory (e.g., DRAM 1532), non-volatile memory (e.g., ROM 1535 or MRAM 1530), a graphics processor 1522, an antenna 1525, touchscreen display 1515 battery 1510, power amplifier 1521, global positioning system (GPS) device 1540, compass 1545, speaker 1520, camera, 1541, and mass storage device (such as hard disk drive, solid-state drive (SSD), compact disk (CD), digital versatile disk (DVD), and so forth), or the like.

Communication chips 1506 may enable wireless communications for the transfer of data to and from the computing device 1500. The term “wireless” and its derivatives may be used to describe circuits, devices, systems, methods, techniques, communications channels, etc., that may communicate data through the use of modulated electromagnetic radiation through a non-solid medium. The term does not imply that the associated devices do not contain any wires, although in some embodiments they might not. Communication chips 1506 may implement any of a number of wireless standards or protocols, including but not limited to those described elsewhere herein. As discussed, computing device 1500 may include a plurality of communication chips 1506. For example, a first communication chip may be dedicated to shorter-range wireless communications, such as Wi-Fi and Bluetooth, and a second communication chip may be dedicated to longer-range wireless communications such as GPS, EDGE, GPRS, CDMA, WiMAX, LTE, Ev-DO, and others.

While certain features set forth herein have been described with reference to various implementations, this description is not intended to be construed in a limiting sense. Hence, various modifications of the implementations described herein, as well as other implementations, which are apparent to persons skilled in the art to which the present disclosure pertains are deemed to lie within the spirit and scope of the present disclosure.

In first examples, a photonic integrated circuit (PIC) comprises a photonic waveguide over a substrate. The waveguide comprises crystalline Si. The PIC comprises an optical cladding material adjacent to a sidewall of the waveguide and over a first length of the waveguide, and a photodetector structure over a second length of the waveguide. The second length of the waveguide comprises impurities of a first conductivity type. The photodetector structure comprises a first material comprising Ge over at least a portion of the second length of the waveguide, and a second material between a sidewall of the first material and a sidewall of the cladding material. The second material is in direct contact with the sidewall of the first material.

In second examples, for any of the first examples the second material has a first lateral width adjacent to the sidewall of the first material that is less than a second lateral width of a space between the sidewall of the first material and the sidewall of the cladding material.

In third examples, for any of the first through second examples the PIC further comprises a dielectric material between the second material and the cladding material, wherein the dielectric material has a different chemical composition than both the second material and the cladding material.

In fourth examples, for any of the first through third examples the first lateral width of the second material varies from a greater width proximal to the second length of the waveguide to a smaller width distal from the second length of the waveguide.

In fifth examples, for any of the first through fourth examples the cladding material comprises silicon and oxygen, the first material is monocrystalline Ge, and the photodetector structure further comprises a layer comprising Si over the first material. The layer comprising Si has a second conductivity type.

In sixth examples, for any of the first through sixth examples the second material comprises at least one of, silicon, oxygen or nitrogen.

In seventh examples, for any of the sixth examples the second material comprises crystalline silicon.

In eighth examples, a photonic integrated circuit (PIC) comprises a photonic waveguide over a substrate. The waveguide comprises crystalline Si. The PIC comprises an optical cladding material adjacent to a sidewall of the waveguide and over a first length of the waveguide. The PIC comprises a photodetector structure over a second length of the waveguide. The second length of the waveguide comprises impurities of a first conductivity type, and the photodetector structure comprises a first material comprising crystalline Si over the top of the second length of the waveguide, a second material comprising Ge over a first crystal facet of the first material, and a third material over a second crystal facet of the first material, and between a sidewall of the second material and a sidewall of the cladding material.

In ninth examples, for any of the eighth examples the first crystal facet is a (100) plane of the first material, and the second facet is a (111) plane of the first material, or a plane of an even higher index.

In tenth examples, for any of the eighth through ninth examples the second material is in direct contact with the first crystal facet, and the third material is in direct contact with the second crystal facet.

In eleventh examples, for any of the eighth through tenth examples a first portion of the first material is encircled by a second portion of the first material that is below the third material. The first portion comprises impurities of a second, complementary, conductivity type. The first portion has a lower concentration of impurities of the first conductivity type than the first region, and a lower concentration of impurities of the second conductivity type than the second length of the waveguide.

In twelfth examples, for any of the eleventh examples the second material is in direct contact with the sidewall of the cladding material and extends a lateral width from the sidewall of the cladding material.

In thirteenth examples, for any of the eleventh through twelfth examples the photodetector structure further comprises a layer comprising Si over the second material, wherein the layer comprising Si further comprises impurities of the second conductivity type.

In fourteenth examples, a PIC comprises a photonic waveguide over a substrate, wherein the waveguide comprises crystalline Si, an optical cladding material adjacent to a sidewall of the waveguide and over a first length of the waveguide, and a photodetector structure over a second length of the waveguide. The second length of the waveguide comprises impurities of a first conductivity type. The photodetector structure comprises a first material comprising Ge adjacent to a sidewall of the cladding material, and a second material between the first material and the second length of the waveguide. The second material comprises crystalline Si, a first portion of the second material comprises impurities of a second conductivity type, and a second portion of the of the second material having a lower concentration of impurities than either the first portion or the second length of the waveguide is embedded within the second length of the waveguide.

In fifteenth examples, for any of the fourteenth examples the first length of the waveguide has first thickness, and the second length of the waveguide has a second thickness equal to 30-80% of the first thickness.

In sixteenth examples, for any of the fourteenth through fifteenth examples the second material has a third thickness over the second thickness, the third thickness at least equal to the difference between the first and second thicknesses.

In seventeenth examples, for any of the fourteenth through sixteenth examples the photodetector structure comprises a layer of Si over the first material, wherein the layer of Si has the second conductivity type.

In eighteenth examples, for any of the fourteenth through seventeenth examples the PIC further comprises contact metallization in direct contact with an impurity doped portion of the waveguide that is adjacent to the second material.

In nineteenth examples for any of the fourteenth through eighteenth examples the second length of the waveguide below the second material has a thickness of 30-80% of that of the first length of the waveguide.

In twentieth examples, for any of the fourteenth through nineteenth examples a (100) plane of the second material intersects a sidewall of the cladding material.

It will be recognized that principles of the disclosure are not limited to the embodiments so described, but can be practiced with modification and alteration without departing from the scope of the appended claims. The above embodiments may include the undertaking only a subset of such features, undertaking a different order of such features, undertaking a different combination of such features, and/or undertaking additional features than those features explicitly listed. The scope of the embodiments should, therefore, be determined with reference to the appended claims, along with the full scope of equivalents to which such claims are entitled.

What is claimed is:

1. A photonic integrated circuit (PIC), comprising:
a photonic waveguide over a substrate, wherein the waveguide comprises crystalline Si;
an optical cladding material adjacent to a sidewall of the waveguide and over a first length of the waveguide; and
a photodetector structure over a second length of the waveguide, wherein:
the second length of the waveguide comprises impurities of a first conductivity type and
the photodetector structure comprises:
a first material comprising Ge over at least a portion of the second length of the waveguide; and
a second material between a sidewall of the first material and a sidewall of the cladding material, wherein the second material is in direct contact with the sidewall of the first material.

2. The PIC of claim 1, wherein the second material has a first lateral width adjacent to the sidewall of the first material that is less than a second lateral width of a space between the sidewall of the first material and the sidewall of the cladding material.

3. The PIC of claim 2, further comprising a dielectric material between the second material and the cladding material, wherein the dielectric material has a different chemical composition than both the second material and the cladding material.

4. The PIC of claim 2, wherein the first lateral width of the second material varies from a greater width proximal to the second length of the waveguide to a smaller width distal from the second length of the waveguide.

5. The PIC of claim 1, wherein:
the cladding material comprises silicon and oxygen;
the first material is monocrystalline Ge; and
the photodetector structure further comprises a layer comprising Si over the first material, the layer comprising Si having a second conductivity type.

6. The PIC of claim 1, wherein the second material comprises at least one of, silicon, oxygen or nitrogen.

7. The PIC of claim 6, wherein the second material comprises crystalline silicon.

8. A photonic integrated circuit (PIC), comprising:
a photonic waveguide over a substrate, wherein the waveguide comprises crystalline Si;
an optical cladding material adjacent to a sidewall of the waveguide and over a first length of the waveguide; and
a photodetector structure over a second length of the waveguide, wherein
the second length of the waveguide comprises impurities of a first conductivity type; and
the photodetector structure comprises:
a first material comprising crystalline Si over the top of the second length of the waveguide;
a second material comprising Ge over a first crystal facet of the first material; and
a third material over a second crystal facet of the first material, and between a sidewall of the second material and a sidewall of the cladding material.

9. The PIC of claim 8, wherein:
the first crystal facet is a (100) plane of the first material; and
the second facet is a (111) plane of the first material, or a plane of an even higher index.

10. The PIC of claim 9, wherein:
the second material is in direct contact with the first crystal facet; and
the third material is in direct contact with the second crystal facet.

11. The PIC of claim 8, wherein:
a first portion of the first material is encircled by a second portion of the first material that is below the third material;
the first portion comprises impurities of a second, complementary, conductivity type; and
first portion has a lower concentration of impurities of the first conductivity type than the first region, and a lower concentration of impurities of the second conductivity type than the second length of the waveguide.

12. The PIC of claim 11, wherein the second material is in direct contact with the sidewall of the cladding material and extends a lateral width from the sidewall of the cladding material.

13. The PIC of claim 11, wherein the photodetector structure further comprises a layer comprising Si over the second material, wherein the layer comprising Si further comprises impurities of the second conductivity type.

14. A photonic integrated circuit (PIC), comprising:
a photonic waveguide over a substrate, wherein the waveguide comprises crystalline Si;
an optical cladding material adjacent to a sidewall of the waveguide and over a first length of the waveguide; and
a photodetector structure over a second length of the waveguide, wherein:
the second length of the waveguide comprises impurities of a first conductivity type; and
the photodetector structure comprises:
a first material comprising Ge adjacent to a sidewall of the cladding material; and
a second material between the first material and the second length of the waveguide, wherein:
the second material comprises crystalline Si;
a first portion of the second material comprises impurities of a second conductivity type, and
a second portion of the of the second material having a lower concentration of impurities than either the first portion or the second length of the waveguide is embedded within the second length of the waveguide.

15. The PIC of claim 14, wherein:
the first length of the waveguide has first thickness; and
the second length of the waveguide has a second thickness equal to 30-80% of the first thickness.

16. The PIC of claim 14, wherein the second material has a third thickness over the second thickness, the third thickness at least equal to the difference between the first and second thicknesses.

17. The PIC of claim 14, wherein the photodetector structure comprises a layer of Si over the first material, wherein the layer of Si has the second conductivity type.

18. The PIC of claim 14, further comprising contact metallization in direct contact with an impurity doped portion of the waveguide that is adjacent to the second material.

19. The PIC of claim 14, wherein the second length of the waveguide below the second material has a thickness of 30-80% of that of the first length of the waveguide.

20. The PIC of claim 14, wherein a (100) plane of the second material intersects a sidewall of the cladding material.
